(19) United States
(12) Patent Application Publication
(10) Pub. No.: US 2024/0329523 A1
(43) Pub. Date: Oct. 3, 2024

(54) RADIATION-SENSITIVE COMPOSITION AND METHOD OF FORMING RESIST PATTERN

(71) Applicant: JSR CORPORATION, Tokyo (JP)

(72) Inventor: Ken MARUYAMA, Tokyo (JP)

(73) Assignee: JSR CORPORATION, Tokyo (JP)

(21) Appl. No.: 18/618,304

(22) Filed: Mar. 27, 2024

(30) Foreign Application Priority Data
Mar. 28, 2023 (JP) 2023-051889
Dec. 21, 2023 (JP) 2023-216301

(51) Int. Cl. G03F 7/004; C08F 212/14; C08F 220/30; G03F 7/038; G03F 7/039

(52) U.S. Cl. CPC G03F 7/0045; C08F 212/24; C08F 220/301; G03F 7/038; G03F 7/039

(57) ABSTRACT

A radiation-sensitive composition includes: a polymer comprising a first structural unit represented by formula (1); and a compound comprising an anion and a radiation-sensitive onium cation. At least one of the polymer and the compound has a ring structure having at least one iodine atom bonded to the ring structure. R¹ represents a hydrogen atom, a fluorine atom, a methyl group, or a trifluoromethyl group; L¹ represents a single bond, —COO—, or —CONH—; Ar¹ represents a group obtained by removing two hydrogen atoms from a substituted or unsubstituted aromatic hydrocarbon ring; and R² represents an acid-labile group.

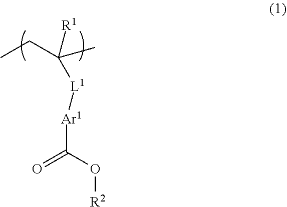

### CROSS-REFERENCE TO RELATED APPLICATIONS

The present application claims priority to Japanese patent application No. 2023-51889 filed Mar. 28, 2023 and to Japanese patent application No. 2023-216301 filed Dec. 21, 2023. The contents of these applications are incorporated herein by reference in their entirety.

### BACKGROUND OF THE DISCLOSURE

### Technical Field

The present disclosure relates to a radiation-sensitive composition and a method of forming a resist pattern.

### Discussion of the Background

A radiation-sensitive composition for use in microfabrication by lithography generates an acid at light-exposed regions upon an irradiation with a radioactive ray, e.g., an electromagnetic wave such as a far ultraviolet ray such as an ArF excimer laser beam (wavelength of 193 nm), a KrF excimer laser beam (wavelength of 248 nm), etc. or an extreme ultraviolet ray (EUV) (wavelength of 13.5 nm), or a charged particle ray such as an electron beam. A chemical reaction in which the acid serves as an origin causes a difference between the light-exposed regions and light-unexposed regions in rates of dissolution in a developer solution, whereby a resist pattern is formed on a substrate.

Such a radiation-sensitive composition is required not only to have favorable sensitivity to a radioactive ray such as an extreme ultraviolet ray and an electron beam, but also to have superiority in terms of resolution, CDU (Critical Dimension Uniformity), and the like.

Types, molecular structures, and the like of polymers, acid generating agents, and other components which may be used in radiation-sensitive compositions have been investigated to meet these requirements, and combinations thereof have been further investigated in detail (see Japanese Unexamined Patent Application, Publication No. 2010-134279, Japanese Unexamined Patent Application, Publication No. 2014-224984 and Japanese Unexamined Patent Application, Publication No. 2016-047815, and Japanese Unexamined Patent Application, Publication No. 2021-009357).

### SUMMARY

According to an aspect of the present disclosure, a radiation-sensitive composition includes: a polymer comprising a first structural unit represented by formula (1); and a compound comprising an anion and a radiation-sensitive onium cation. At least one of the polymer and the compound has a ring structure having at least one iodine atom bonded to the ring structure. R¹ represents a hydrogen atom, a fluorine atom, a methyl group, or a trifluoromethyl group; L¹ represents a single bond, —COO—, or —CONH—; Ar¹ represents a group obtained by removing two hydrogen atoms from a substituted or unsubstituted aromatic hydrocarbon ring; and R² represents an acid-labile group.

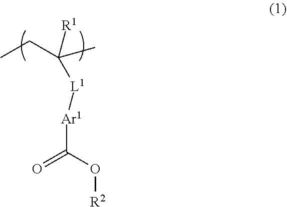

According to another aspect of the present disclosure, a method of forming a resist pattern, includes: applying the above-described radiation-sensitive composition directly or indirectly on a substrate to form a resist film; exposing the resist film; and developing the resist film exposed.

### DESCRIPTION OF THE EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

According to an embodiment of the present disclosure, a radiation-sensitive composition contains: a polymer having a first structural unit represented by the following formula (1); and a compound having an anion and a radiation-sensitive onium cation, wherein at least one of the polymer and the compound has a ring structure obtained by substituting at least one hydrogen atom with an iodine atom.

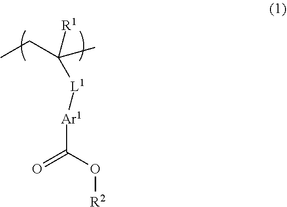

In the formula (1), R¹ represents a hydrogen atom, a fluorine atom, a methyl group, or a trifluoromethyl group; L¹ represents a single bond, —COO—, or —CONH—; Ar¹ represents a group obtained by removing two hydrogen atoms from a substituted or unsubstituted aromatic hydrocarbon ring; and R² represents an acid-labile group.

According to another embodiment of the present disclosure, a method of forming a resist pattern includes: applying the above-described radiation-sensitive composition directly or indirectly on a substrate; exposing a resist film formed by the applying; and developing the resist film exposed.

The radiation-sensitive composition of the present disclosure is superior in sensitivity, resolution, and CDU. The method of forming a resist pattern of the present disclosure enables a resist pattern that is superior in resolution and CDU to be formed with favorable sensitivity.

The radiation-sensitive composition and the method of forming a resist pattern of the present disclosure are described in detail below.

### Radiation-Sensitive Composition

The radiation-sensitive composition of one embodiment of the present disclosure contains: a polymer (hereinafter, may be also referred to as “(A) polymer” or “polymer (A)”) having a structural unit represented by the formula (1) described later; and a compound (hereinafter, may be also referred to as “(Z) compound” or “compound (Z)”) having an anion and a radiation-sensitive onium cation. At least one of the polymer (A) and the compound (Z) has a ring structure (hereinafter, may be also referred to as “ring structure (p)”) obtained by substituting at least one hydrogen atom with an iodine atom.

The radiation-sensitive composition typically contains an organic solvent (hereinafter, may be also referred to as “(D) organic solvent” or “organic solvent (D)”). The radiation-sensitive composition may also contain a polymer (hereinafter, may be also referred to as “(F) polymer” or “polymer (F)”) having a percentage content of fluorine atoms greater than that of the polymer (A). The radiation-sensitive composition may contain, within a range not leading to impairment of the effects of the present invention, other optional component(s).

Due to the polymer (A) and the compound (Z) being contained, and a ring structure (p) being included in at least one of the polymer (A) and compound (Z), the radiation-sensitive composition is superior in sensitivity, resolution, and CDU. Although not necessarily clarified and without wishing to be bound by any theory, the reason for achieving the aforementioned effects by the radiation-sensitive composition due to involving such a constitution may be presumed, for example, as in the following. It is believed that since an iodine atom is highly efficient in absorbing radioactive rays, and the compound (Z) has the ring structure (p), generation efficiency of an acid from the compound (Z) in light-exposed regions is improved. Furthermore, it is considered that in the case in which the polymer (A) has the ring structure (p), more secondary electrons are released from the polymer (A) in light-exposed regions, and receiving the secondary electrons also improves generation efficiency of the acid from the compound (Z). It is considered that as a result, the radiation-sensitive composition is superior in sensitivity and resolution. It is presumed that in the case in which the polymer (A) has the ring structure (p), an interaction occurs between the polymer (A) and the compound (Z), and in the case in which the compound (Z) has the ring structure (p), an interaction occurs between molecules of the compound (Z), whereby diffusion of the acid generated by exposure into light-unexposed regions is appropriately inhibited. It is considered that as a result, the radiation-sensitive composition is superior not only in sensitivity and resolution, but also in CDU.

The radiation-sensitive composition can be prepared by, for example: mixing the polymer (A) and the compound (Z), and as needed, an acid generating agent (B), an acid diffusion control agent (C), the organic solvent (D), the polymer (F), other optional component(s), and the like in a predefined proportion; and filtering a thus obtained mixture through a membrane filter having a pore size of 0.2 μm or less.

Each component contained in the radiation-sensitive composition is described below.

### Ring Structure (p)

The ring structure (p) is a structure included in at least one of the polymer (A) and the compound (Z) described later. The ring structure (p) is a ring structure obtained by substituting at least one hydrogen atom with an iodine atom. In other words, the ring structure (p) has an iodine atom substituted for at least one hydrogen atom bonding to the atom constituting the ring structure. The iodine atom may be included in the ring structure (p) in a form of either a monovalent iodo group (*—I, wherein * denotes a binding site to the ring structure), or an iodonium group (*—I⁺R, wherein *denotes a binding site to the ring structure, and R represents a substituted or unsubstituted hydrocarbon group). The ring structure (p) is preferably a ring structure obtained by substituting at least one hydrogen atom with a monovalent iodo group. The number of occurrences of substitution with an iodine atom is not particularly limited and may be appropriately predetermined as long as the number is no less than 1, and is, for example, 1 to 5, and preferably 1 to 3. The case in which the number of substitution with an iodine atom is no less than 2 is preferred since resolution and CDU tend to be more improved with favorable sensitivity, as compared with the case of the number of substitution with an iodine atom being 1.

The case of the ring structure (p) being included in at least the polymer (A) is preferred since CDU tends to be more improved, the case of the ring structure (p) being included in at least compound (Z) is preferred since resolution tends to be more improved, and the case of the ring structure (p) being included in both the polymer (A) and the compound (Z) is preferred since sensitivity, resolution, and CDU tend to be more improved.

The “ring structure” may encompass an “aliphatic ring” and an “aromatic ring”. The “aliphatic ring” may encompass an “aliphatic hydrocarbon ring” and an “aliphatic heteroring”. Of alicyclic structures, polycyclic structures involving the aliphatic hydrocarbon ring and the aliphatic heteroring are defined as falling under the category of the “aliphatic heteroring”. The “aromatic ring” may encompass an “aromatic hydrocarbon ring” and an “aromatic heteroring”. Of aromatic rings, polycyclic aromatic rings involving the aromatic hydrocarbon ring and the aromatic heteroring are defined as falling under the category of the “aromatic heteroring”.

The number of ring atoms of a ring structure that gives the ring structure (p) is not particularly limited and is, for example, 3 to 30, and preferably 5 to 20. The number of “ring atoms” as referred to herein means the number of atoms constituting a ring structure, and in the case of a polycycle, the number of “ring atoms” means the number of atoms constituting the polycycle. The “polycycle” may encompass not only a spiro polycycle, in which two rings have one shared atom, and a fused polycycle, in which two rings have two shared atoms, but also a ring-assembled polycycle in which two rings are connected by a single bond without having any shared atom.

The ring structure that gives the ring structure (p) is exemplified by aliphatic hydrocarbon rings having 3 to 30 ring atoms, aliphatic heterorings having 3 to 30 ring atoms, aromatic hydrocarbon rings having 6 to 30 ring atoms, and aromatic heterorings having 5 to 30 ring atoms.

Examples of the aliphatic hydrocarbon ring include: monocyclic saturated aliphatic rings such as a cyclopentane ring, a cyclohexane ring, a cycloheptane ring, a cyclooctane ring, a cyclononane ring, a cyclodecane ring, and a cyclododecane ring; monocyclic unsaturated aliphatic rings such as a cyclopentene ring, a cyclohexene ring, a cycloheptene ring, a cyclooctene ring, and a cyclodecene ring; polycyclic saturated aliphatic rings such as a norbornane ring, an adamantane ring, a tricyclodecane ring, a tetracyclododecane ring, and a steroid ring; and polycyclic unsaturated aliphatic rings such as a norbornene ring and a tricyclodecene ring. The “steroid ring” as referred to means a ring structure having, as a basic skeleton, a skeleton (sterane skeleton) provided by condensation of three 6-membered rings and one 4-membered ring.

Examples of the aliphatic heteroring include: lactone structures such as a γ-valerolactone ring, a hexanolactone ring, and a norbornanelactone ring; sultone structures such as a hexanosultone ring and a norbornanesultone ring; oxygen atom-containing heterorings such as a dioxolane ring, an oxacycloheptane ring, and an oxanorbornane ring; nitrogen atom-containing heterorings such as an azacyclohexane ring and a diazabicyclooctane ring; sulfur atom-containing heterorings such as a thiacyclohexane ring and a thianorbornane ring.

Examples of the aromatic hydrocarbon ring include: a benzene ring; condensed polycyclic aromatic hydrocarbon rings such as a naphthalene ring, an anthracene ring, a fluorene ring, a biphenylene ring, a phenanthrene ring, and a pyrene ring; ring-assembled aromatic hydrocarbon rings such as a biphenyl ring, a terphenyl ring, a binaphthalene ring, and a phenylnaphthalene ring; and a 9,10-ethanoanthracene ring.

Examples of the aromatic heteroring include: oxygen atom-containing heterorings such as a furan ring, a pyran ring, a benzofuran ring, and a benzopyran ring; nitrogen atom-containing heterorings such as a pyridine ring, a pyrimidine ring, and an indole ring; sulfur atom-containing heterorings such as a thiophene ring.

The ring structure that gives the ring structure (p) is preferably the aromatic hydrocarbon ring having 6 to 30 ring atoms, and more preferably a benzene ring. In this case, there is a tendency to enable further improving the sensitivity.

In the ring structure (p), at least one hydrogen atom may be further substituted with a substituent other than an iodine atom. The substituent is exemplified by a halogen atom other than an iodine atom, a hydroxy group, a carboxy group, a cyano group, a nitro group, an alkyl group, a fluorinated alkyl group (a group obtained by substituting at least one hydrogen atom included in an alkyl group, with a fluorine atom), an alkoxy group, an alkoxycarbonyl group, an alkoxycarbonyloxy group, an acyl group, and an acyloxy group. In the case in which the ring structure that gives the ring structure (p) is an aromatic ring, the substituent is preferably a fluorine atom or the fluorinated alkyl group. In this case, there is a tendency to enable further improving the sensitivity and CDU.

### (A) Polymer

The polymer (A) has a structural unit (hereinafter, may be also referred to as “structural unit ma”) represented by the formula (1) described later. The polymer (A) is a polymer, the solubility of which in a developer solution is capable of being altered by an action of an acid. Without wishing to be construed restrictively, the polymer (A) may exert the property of alteration of the solubility in a developer solution by the action of an acid, due to having the structural unit ma. The radiation-sensitive composition can contain one type, or two or more types of the polymer (A).

The polymer (A) may further have a structural unit (hereinafter, may be also referred to as “structural unit mb”) which includes an acid-labile group and is a structural unit other than the structural unit ma. The polymer (A) preferably further has a structural unit (hereinafter, may be also referred to as “structural unit mc”) that includes a phenolic hydroxyl group. The polymer (A) may further have an other structural unit (hereinafter, may be also referred to as “structural unit md”) aside from the structural unit ma, the structural unit mb, and the structural unit mc. The polymer (A) can have one type, or two or more types of each structural unit.

In the case in which the polymer (A) has the ring structure (p), the polymer (A) preferably has a structural unit (hereinafter, may be also referred to as “structural unit mx”) that includes the ring structure (p). The structural unit mx falls under the category of any of the structural unit ma, the structural unit mb, the structural unit mc, and the structural unit md. For example, in the case in which the structural unit ma includes the ring structure (p), the structural unit mx falls under the category of the structural unit ma.

The lower limit of a proportion of the polymer (A) contained in the radiation-sensitive composition is, with respect to total components other than the organic solvent (D) contained in the radiation-sensitive composition, preferably 50% by mass, more preferably 70% by mass, and still more preferably 80% by mass. The upper limit of the proportion is preferably 99% by mass, and more preferably 95% by mass.

The lower limit of a polystyrene equivalent weight average molecular weight (Mw) of the polymer (A) as determined by gel permeation chromatography (GPC) is preferably 1,000, more preferably 2,000, still more preferably 3,000, and even further preferably 5,000. The upper limit of the Mw is preferably 30,000, more preferably 20,000, still more preferably 10,000, and even further preferably 8,000. When the Mw of the polymer (A) falls within the above range, coating characteristics of the radiation-sensitive composition can be improved. The Mw of the polymer (A) can be regulated by adjusting, for example, a type and/or a using amount, etc., of a polymerization initiator to be used in synthesis of the polymer (A).

The upper limit of a ratio (hereinafter, may be also referred to as “Mw/Mn” or “polydispersity”) of Mw to a polystyrene-equivalent number average molecular weight (Mn) of the polymer (A) as determined by GPC is preferably 2.5, more preferably 2.0, still more preferably 1.8, and even further preferably 1.7. The lower limit of the ratio is typically 1.0, preferably 1.1, more preferably 1.2, still more preferably 1.3, and even further preferably 1.4.

### Methods of Measuring Mw and Mn

As referred to herein, Mw and Mn of the polymer are values measured by using gel permeation chromatography (GPC) under the following conditions.
GPC columns: “G2000 HXL”×2, “G3000 HXL”×1, and “G4000 HXL”×1, available from Tosoh Corporation
column temperature: 40° C.
elution solvent: tetrahydrofuran
flow rate: 1.0 mL/min
sample concentration: 1.0% by mass
amount of injected sample: 100 uL
detector: differential refractometer
standard substance: mono-dispersed polystyrene

The polymer (A) can be synthesized by, for example, polymerizing a monomer that gives each structural unit by a well-known method.

Each structural unit included in the polymer (A) is described below.

### Structural Unit Ma

The structural unit ma is a structural unit represented by the following formula (1). The polymer (A) can have one type, or two or more types of the structural unit ma.

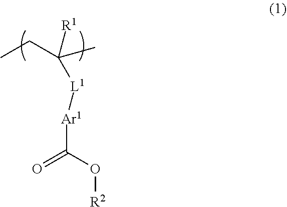

In the above formula (1), R¹ represents a hydrogen atom, a fluorine atom, a methyl group, or a trifluoromethyl group; L¹ represents a single bond, —COO—, or —CONH—; Ar¹ represents a group obtained by removing two hydrogen atoms from a substituted or unsubstituted aromatic hydrocarbon ring; and R² represents an acid-labile group.

The structural unit ma is a structural unit which includes an acid-labile group (hereinafter, may be also referred to as “acid-labile group (a)”) represented by R². The “acid-labile group” as referred to herein means a group that substitutes for a hydrogen atom in a carboxy group and is capable of being dissociated by an action of an acid to give a carboxy group. The acid-labile group (a) is a group that substitutes for a hydrogen atom included in the carboxy group. In other words, in the structural unit ma, the acid-labile group (a) bonds to an ethereal oxygen atom of a carbonyloxy group.

Due to having the structural unit ma, the polymer (A) enables forming a resist pattern since the acid-labile group (a) is dissociated from the structural unit ma by an action of the acid generated from the compound (Z), the acid generating agent (B), and/or the like upon exposure, whereby a difference is generated in the solubility of the polymer (A) in the developer solution, between light-exposed regions and light-unexposed regions. The feature that the polymer (A) has the structural unit ma is considered to be one factor in the radiation-sensitive composition exhibiting superior sensitivity, resolution, and CDU.

R¹ represents, in light of a degree of copolymerization of a monomer that gives the structural unit ma, preferably a hydrogen atom or a methyl group.

L¹ represents preferably a single bond or —COO—. It is to be noted that in the case in which L¹ represents-COO—, with respect to a direction of bonding of this group, —COO—* is preferred, wherein * denotes a binding site with Ar¹.

A “group obtained by removing X hydrogen atoms from a ring structure” as referred to means a group obtained by removing X hydrogen atoms bonding to atoms that constitute the ring structure.

The number of ring atoms and the type of an aromatic hydrocarbon ring that gives Ar¹ are exemplified by the aromatic hydrocarbon ring having 6 to 30 ring atoms exemplified in the above section of Ring Structure (p). The aromatic hydrocarbon ring that gives Ar¹ is preferably a benzene ring or a naphthalene ring.

In the aromatic hydrocarbon ring that gives Ar¹, at least one hydrogen atom may be further substituted with a substituent. The substituent is exemplified by an iodine atom, and substituents exemplified in the above section of Ring Structure (p).

The acid-labile group (a) not having the polycyclic aliphatic ring is preferred due to a tendency to enable further improving the resolution.

The acid-labile group (a) having the aromatic ring or a carbon-carbon double bond is preferred due to a tendency to enable further improving the resolution.

The acid-labile group (a) having the aromatic ring obtained by substituting at least one hydrogen atom with an iodine atom is preferred due to a tendency to enable improving the sensitivity and CDU.

The acid-labile group (a) represented by R² is exemplified by a group (hereinafter, may be also referred to as “acid-labile group (a-1)”) represented by the following formula (a-1).

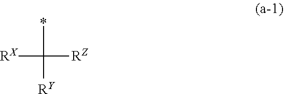

In the above formula (a-1), * denotes a binding site to the ethereal oxygen atom of the carboxy group in the above formula (1); R^{X} represents a substituted or unsubstituted monovalent hydrocarbon group having 1 to 20 carbon atoms; R^{Y} and R^{Z} each independently represent a monovalent hydrocarbon group having 1 to 20 carbon atoms, or R^{Y} and R^{Z} taken together represent an aliphatic ring having 3 to 20 ring atoms together with the carbon atom to which R^{Y} and R^{Z} bond.

The number of “carbon atoms” means the number of carbon atoms constituting a group. The “hydrocarbon group” may encompass an “aliphatic hydrocarbon group” and an “aromatic hydrocarbon group”. The “aliphatic hydrocarbon group” may encompass a “chain hydrocarbon group” and an “alicyclic hydrocarbon group”. From another viewpoint, the “aliphatic hydrocarbon group” may encompass a “saturated hydrocarbon group” and an “unsaturated hydrocarbon group”. The “chain hydrocarbon group” as referred to herein means a hydrocarbon group not having a ring structure but being constituted with only a chain structure, and may be exemplified by both a linear hydrocarbon group and a branched hydrocarbon group. The “alicyclic hydrocarbon group” as referred to herein means a hydrocarbon group having, as a ring structure, not an aromatic ring but an aliphatic ring alone, and may be exemplified by both a monocyclic alicyclic hydrocarbon group and a polycyclic alicyclic hydrocarbon group. With regard to this, it is not necessary for the alicyclic hydrocarbon group to be constituted with only an aliphatic ring; it may have a chain structure in a part thereof. The “aromatic hydrocarbon group” as referred to herein means a hydrocarbon group that includes an aromatic ring as a ring structure. With regard to this, it is not necessary for the aromatic hydrocarbon group to be constituted with only an aromatic ring, and it may have a chain structure or an aliphatic ring in a part thereof.

The monovalent hydrocarbon group having 1 to 20 carbon atoms that gives R^{Y}, R^{Y}, or R^{Z} is exemplified by a monovalent chain hydrocarbon group having 1 to 20 carbon atoms, a monovalent alicyclic hydrocarbon group having 3 to 20 carbon atoms, and a monovalent aromatic hydrocarbon group having 6 to 20 carbon atoms.

Examples of the substituent which may be incorporated in the hydrocarbon group represented by R^{X} include halogen atoms such as a fluorine atom and an iodine atom, a hydroxy group, a carboxy group, a cyano group, a nitro group, an alkoxy group, an alkoxycarbonyl group, an alkoxycarbonyloxy group, an acyl group, and an acyloxy group. The case in which R^{X} has an iodine atom as the substituent is preferred due to a tendency to enable further improving the sensitivity and CDU of the radiation-sensitive composition.

Examples of the monovalent alicyclic hydrocarbon group having 3 to 20 carbon atoms include: monocyclic alicyclic saturated hydrocarbon groups such as a cyclopentyl group and a cyclohexyl group; polycyclic alicyclic saturated hydrocarbon groups such as a norbornyl group, an adamantyl group, a tricyclodecyl group, and a tetracyclododecyl group; monocyclic alicyclic unsaturated hydrocarbon groups such as a cyclopentenyl group and a cyclohexenyl group; and polycyclic alicyclic unsaturated hydrocarbon groups such as a norbornenyl group, a tricyclodecenyl group, and a tetracyclododecenyl group.

Examples of the monovalent alicyclic hydrocarbon group having 3 to 20 carbon atoms include: monocyclic alicyclic saturated hydrocarbon groups such as a cyclopentyl group and a cyclohexyl group; polycyclic alicyclic saturated hydrocarbon groups such as a norbornyl group, an adamantyl group, a tricyclodecyl group, and a tetracyclododecyl group; monocyclic alicyclic unsaturated hydrocarbon groups such as a cyclopentenyl group and a cyclohexenyl group; and polycyclic alicyclic unsaturated hydrocarbon groups such as a norbornenyl group, a tricyclodecenyl group, and a tetracyclododecenyl group.

Examples of the monovalent aromatic hydrocarbon group having 6 to 20 carbon atoms include: aryl groups such as a phenyl group, a tolyl group, a xylyl group, a naphthyl group, and an anthryl group; and aralkyl groups such as a benzyl group, a phenethyl group, a naphthylmethyl group, and an anthrylmethyl group.

Examples of the aliphatic ring having 3 to 20 ring atoms which may be represented by R^{Y} and R^{Z}, taken together, together with the carbon atom to which R^{Y} and R^{Z} bond include: monocyclic saturated aliphatic rings such as a cyclopropane ring, a cyclobutane ring, a cyclopentane ring, and a cyclohexane ring; monocyclic unsaturated aliphatic rings such as a cyclopropene ring, a cyclobutene ring, a cyclopentene ring, and a cyclohexene ring; polycyclic saturated aliphatic rings such as a norbornane ring, an adamantane ring, a tricyclodecane ring, and a tetracyclododecane ring; and polycyclic unsaturated aliphatic rings such as a norbornene ring.

In the case in which R^{Y} and R^{Z} each represent the monovalent hydrocarbon group having 1 to 20 carbon atoms, R^{Y} and R^{Z} each represent preferably the chain hydrocarbon group, preferably the alkyl group, and more preferably a methyl group or an ethyl group. R^{X} in this case is preferably the substituted or unsubstituted chain hydrocarbon group, or the substituted or unsubstituted aromatic hydrocarbon group, more preferably an unsubstituted alkyl group, an unsubstituted alkenyl group, or a substituted or unsubstituted aryl group, and still more preferably a methyl group, an ethenyl group, a phenyl group, or an iodophenyl group. The case in which R^{X} represents the alkenyl group or the aryl group is preferred due to a tendency to enable further improving the resolution. The case in which R^{X} represents the aryl group substituted with an iodine atom is preferred due to a tendency to enable further improving the sensitivity and CDU of the radiation-sensitive composition.

In the case in which R^{Y} and R^{Z} taken together represent the aliphatic ring having 3 to 20 ring atoms together with the carbon atom to which R^{Y} and R^{Z} bond, the aliphatic ring is preferably the monocyclic saturated aliphatic ring, and more preferably a cyclopentane ring or a cyclohexane ring. R′ in this case is preferably the substituted or unsubstituted chain hydrocarbon group, or the substituted or unsubstituted aromatic hydrocarbon group, more preferably the unsubstituted alkyl group or the unsubstituted aryl group, and still more preferably a methyl group, an isopropyl group, a t-butyl group, a phenyl group, or an iodophenyl group.

Preferred examples of the acid-labile group (a-1) include groups (hereinafter, may be also referred to as “acid-labile groups (a-1-1) to (a-1-7)”) represented by the following formulae (a-1-1) to (a-1-7).

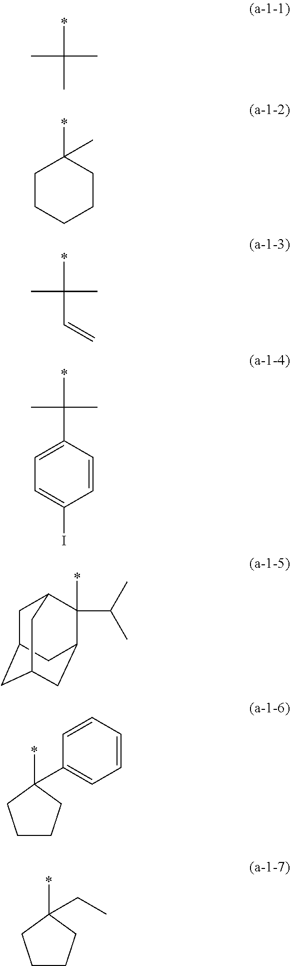

In the above formulae (a-1-1) to (a-1-7), * is as defined in the above formula (a-1).

For example, in the case in which the acid-labile group (a) is the acid-labile group (a-1-4), the polymer (A) containing the ring structure (p) will be provided. In other words, the structural unit ma will fall under the category of the structural unit mx.

Examples of the structural unit ma include structural units (hereinafter, may be also referred to as “structural units (ma-1) to (ma-8)”) represented by the following formulae (ma-1) to (ma-8). It is to be noted that the structural unit (ma-8) falls under the category of also the structural unit mc as described later; however, the structural unit (ma-8) is herein encompassed by the structural unit ma.

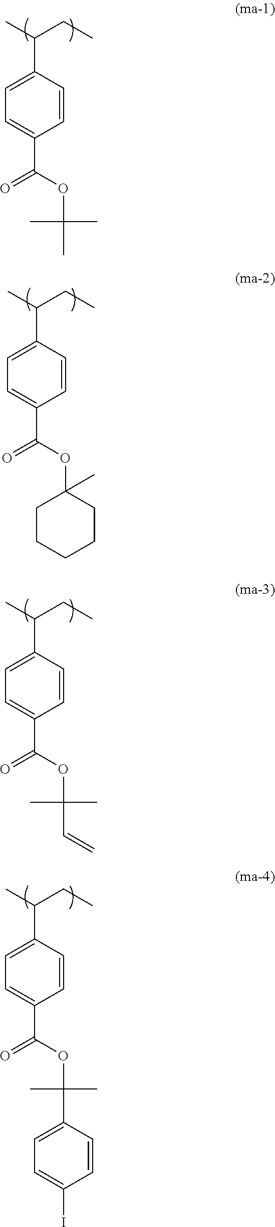

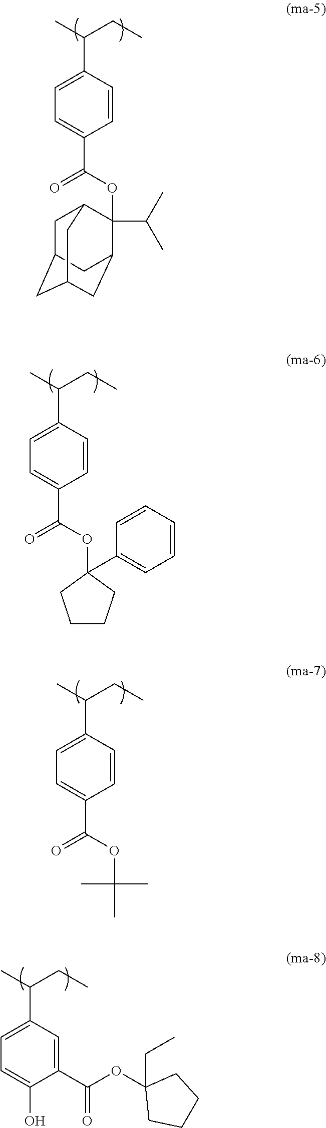

The lower limit of a proportion of the structural unit ma contained in the polymer (A) with respect to the total structural units constituting the polymer (A) is preferably 5 mol %, more preferably 10 mol %, still more preferably 15 mol %, or may be preferably 20 mol %. The upper limit of the proportion is preferably 70 mol %, more preferably 60 mol %, still more preferably 50 mol %, or may be preferably 40 mol %.

### Structural Unit mb

The structural unit mb is a structural unit which includes the acid-labile group, and does not fall under the category of the structural unit ma. The acid-labile group is exemplified by similar groups to the acid-labile group (a) described above.

Examples of the structural unit mb include a structural unit represented by the following formula (2).

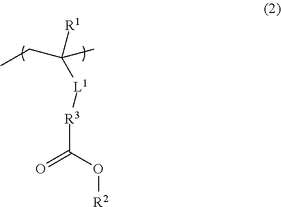

In the above formula (2), R¹, L¹, and R² are as defined in above formula (1). R³ represents a single bond in the case in which L¹ represents a single bond, and R³ represents a substituted or unsubstituted divalent hydrocarbon group in the case in which L¹ represents —COO— or —CONH—.

Details and preferred modes of R¹, L¹, and R² in the above formula (2) are described above. The divalent hydrocarbon group in R³ is exemplified by groups obtained by removing one hydrogen atom from the monovalent hydrocarbon groups having 1 to 20 carbon atoms. Of these, R³ is preferably a group obtained by removing one hydrogen atom from the monovalent chain hydrocarbon group having 1 to 20 carbon atoms, more preferably a group obtained by removing one hydrogen atom from the monovalent alkyl group having 1 to 20 carbon atoms, and still more preferably the alkanediyl group having 1 to 8 carbon atoms.

The structural unit mb may have the ring structure (p). In this case, the structural unit mb falls under the category of the structural unit mx. In the case in which the structural unit mb has the ring structure (p), the ring structure (p) is preferably included in the acid-labile group.

Examples of the structural unit mb include structural units (hereinafter, may be also referred to as “structural units (mb-1) to (mb-6)”) represented by the following formulae (mb-1) to (mb-6).

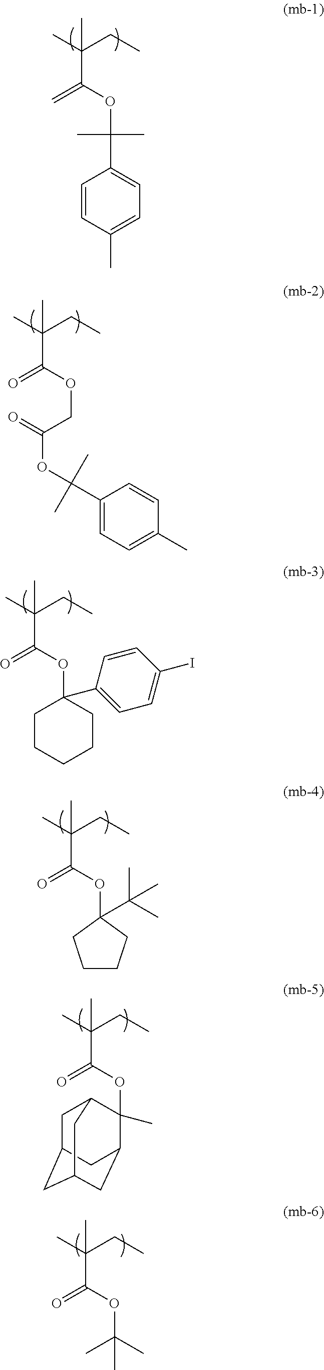

For example, in the case in which the structural unit mb is the structural unit (mb-1), the structural unit (mb-2), or the structural unit (mb-3), the polymer (A) containing the ring structure (p) will be provided. In other words, the structural unit mb will fall under the category of the structural unit mx.

In the case in which the polymer (A) has the structural unit mb, the lower limit of a proportion of the structural unit mb contained in the polymer (A) with respect to the total structural units constituting the polymer (A) is preferably 5 mol %, more preferably 10 mol %, still more preferably 15 mol %, and even further preferably 20 mol %. The upper limit of the proportion is preferably 50 mol %, more preferably 40 mol %, or may be preferably 30 mol %.

### Structural Unit mc

The structural unit mc is a structural unit which includes the phenolic hydroxyl group. The “phenolic hydroxyl group” as referred to herein means not only a hydroxy group directly linking to a benzene ring, but any hydroxy group(s) directly linking to an aromatic ring. The polymer (A) can have one type, or two or more types of the structural unit mc.

In a case of KrF exposure, EUV exposure, or electron beam exposure, due to the polymer (A) having the structural unit mc, sensitivity of the radiation-sensitive composition to the radioactive ray can be more enhanced. Therefore, in the case in which the polymer (A) has the structural unit mc, the radiation-sensitive composition can be suitably used as a radiation-sensitive composition for KrF exposure, for EUV exposure, or for electron beam exposure.

Examples of the structural unit mc include a structural unit represented by the following formula (3).

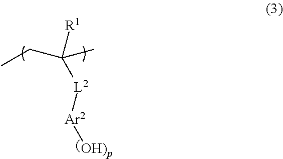

In the above formula (3), R¹ is as defined in the above formula (1); L² represents a single bond, —COO—, —O—, or —CONH—; Ar² represents a group obtained by removing (p+1) hydrogen atoms from a substituted or unsubstituted aromatic hydrocarbon ring; and p is an integer of 1 to 3.

L² represents preferably a single bond or —COO—, and more preferably a single bond. It is to be noted that in the case in which L² represents-COO—, with respect to a direction of bonding of this group, —COO—* is preferred, wherein * denotes a binding site with Ar².

An aromatic hydrocarbon ring that gives Ar² is exemplified by aromatic hydrocarbons ring having 6 to 30 ring atoms exemplified in the above section of Ring Structure (p). The aromatic hydrocarbon ring that gives Ar² is preferably a benzene ring or a naphthalene ring.

In the aromatic hydrocarbon ring that gives Ar², at least one hydrogen atom may be further substituted with a substituent. The substituent is exemplified by an iodine atom, and substituents exemplified in the above section of Ring Structure (p).

p is preferably 1 or 2.

The structural unit mc may have the ring structure (p). In this case, the structural unit mc falls under the category of the structural unit mx. In the case in which the structural unit mc has the ring structure (p), the ring structure (p) is preferably included in Ar². The case in which the ring structure (p) is included in Ar² as referred to herein is exemplified by a case in which Ar² has an iodine atom as a substituent.

Examples of the structural unit mc include structural units (hereinafter, may be also referred to as “structural units (mc-1) to (mc-4)”) represented by the following formulae (mc-1) to (mc-4).

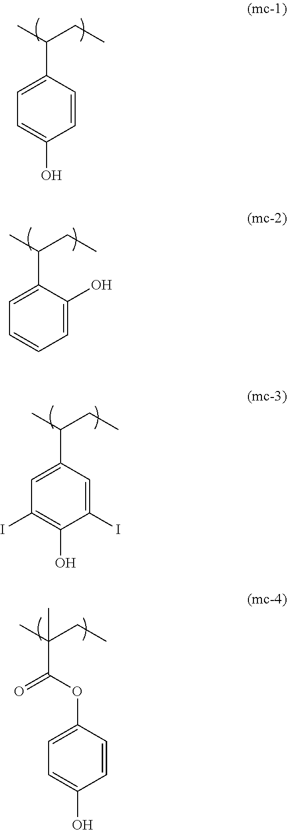

For example, in the case in which the structural unit mc is the structural unit (mc-3), the polymer (A) containing the ring structure (p) will be provided. In other words, the structural unit mc will fall under the category of the structural unit mx.

In the case in which the polymer (A) has the structural unit mc, the lower limit of a proportion of the structural unit mc contained in the polymer (A) with respect to the total structural units constituting the polymer (A) is preferably 20 mol %, more preferably 30 mol %, still more preferably 35 mol %, and particularly preferably 40 mol %. The upper limit of the proportion is preferably 80 mol %, more preferably 70 mol %, still more preferably 65 mol %, and particularly preferably 60 mol %.

### Structural Unit md

The structural unit md is an other structural unit aside from the structural unit ma, the structural unit mb, and the structural unit mc. The structural unit md is exemplified by: a structural unit which includes a lactone structure, a cyclic carbonate structure, a sultone structure, or a combination thereof; a structural unit which includes an alcoholic hydroxyl group, a structural unit derived from a vinylaromatic compound; a structural unit derived from a (meth)acrylic acid ester; and a structural unit which includes a group that generates a sulfonic acid by an action of a radioactive ray.

Examples of the structural unit md include structural units (hereinafter, may be also referred to as “structural units (md-1) to (md-6)”) represented by the following formulae (md-1) to (md-6). It is to be noted that Cat₁⁺ to Cat₂⁺ in the structural units (md-5) to (md-6) are each independently a radiation-sensitive onium cation.

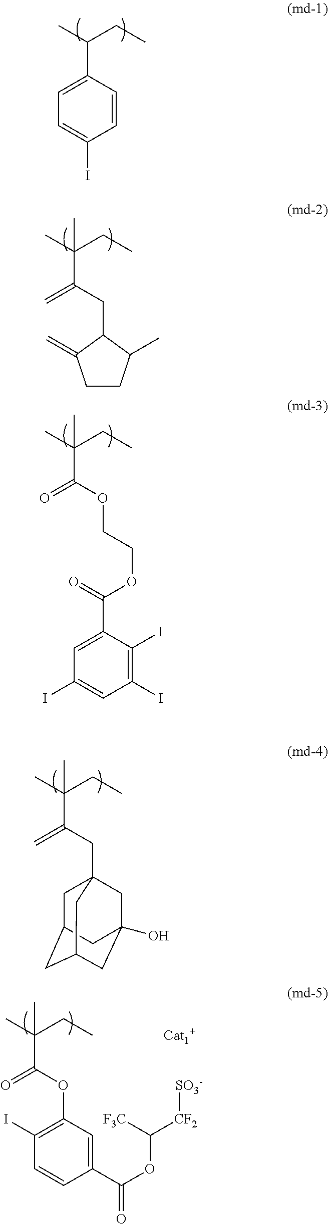

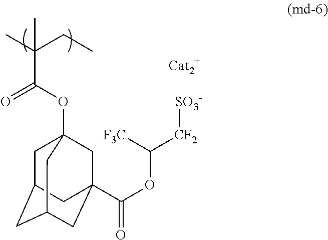

The structural unit (md-1) is a specific example of the structural unit derived from a vinylaromatic compound, and falls under the category of also the structural unit mx. The structural unit (md-2) is a specific example of the structural unit which includes a lactone structure, and falls under the category of also the structural unit mx. The structural unit (md-3) is a specific example of the structural unit derived from a (meth) acrylic acid ester, and falls under the category of also the structural unit mx. The structural unit (md-4) is a specific example of the structural unit which includes an alcoholic hydroxyl group. The structural unit (md-5) is a specific example of the structural unit which includes a group that generates a sulfonic acid by an action of a radioactive ray, and falls under the category of also the structural unit mx. The structural unit (md-6) is a specific example of the structural unit which includes a group that generates a sulfonic acid by an action of a radioactive ray.

Cat₁⁺ to Cat₂⁺ in the structural units (md-5) to (md-6) are exemplified by a cation (Y) in the compound (Z) described later. Here, in a case in which Cat₁⁺ to Cat₂⁺ have a ring structure (p), the structural units (md-5) to (md-6) having the radiation-sensitive onium cations fall under the category of also the structural unit mx.

It is to be noted that, for example, in the case in which Cat₂⁺ incorporated in the structural unit (md-6) is a monovalent cation represented by any of the formula (r-a-3), the formula (r-a-5), or the formula (r-a-6) shown below, the structural unit (md-6) falls under the category of also the structural unit mx. Thus, the structural unit which includes a group that generates a sulfonic acid by an action of a radioactive ray may include the ring structure (p) either in an anionic moiety or in a cationic moiety.

In the case in which the polymer (A) has the structural unit md, the lower limit of a proportion of the structural unit md with respect to the total structural units constituting the polymer (A) is preferably 5 mol %, and more preferably 10 mol %. The upper limit of the proportion is preferably 30 mol %, and still more preferably 20 mol %.

### (Z) Compound

The compound (Z) is a compound (onium salt) having an anion (hereinafter, may be also referred to as “anion (X)”) and a radiation-sensitive onium cation (hereinafter, may be also referred to as “cation (Y)”).

The compound (Z) has, depending on the type of the anion group included in the anion (X): a function of generating an acid in the radiation-sensitive composition by irradiation with a radioactive ray; or a function of controlling a diffusion phenomenon of an acid that occurs in a resist film by the exposure, thereby inhibiting an unwanted chemical reaction (for example, a dissociating reaction of the acid-labile group) in light-unexposed regions. In other words, in the radiation-sensitive composition, the compound (Z) serves as a radiation-sensitive acid generating agent (hereinafter, may be also referred to as “acid generating agent (B)”) or an acid diffusion control agent (quencher) (hereinafter, may be also referred to as “acid diffusion control agent (C)”), depending on the type of the anion group.

In the case in which the compound (Z) serves as the acid generating agent (B), the acid-labile group incorporated in the structural unit ma and/or the like included in the polymer (A) is dissociated due to the acid generated from the compound (Z) by irradiation with a radioactive ray, whereby an acidic group such as a carboxy group is produced to cause a difference in solubility of the resist film into a developer solution, between light-exposed regions and light-unexposed regions, thereby enabling a resist pattern to be formed.

In the case in which the compound (Z) serves as the acid diffusion control agent (C), the acid is generated in light-exposed regions to enhance solubility or insolubility of the polymer (A) in a developer solution, whereas the compound (Z) serves as a quencher through a superior acid-capturing function being exerted due to the anion in light-unexposed regions, whereby the acid diffused from the light-exposed regions is captured. Accordingly, roughness at an interface between the light-exposed regions and light-unexposed regions is improved, and the difference in solubility into a developer solution between the light-exposed regions and the light-unexposed regions is increased, whereby the resolution can be improved.

The radiation-sensitive composition may contain one type, or two or more types of the compound (Z). The radiation-sensitive composition preferably contains the compound (Z) that serves as at least the acid generating agent (B), and more preferably contains both the compound (Z) that serves as the acid generating agent (B), and the compound (Z) that serves as the acid diffusion control agent (C).

In the case in which compound (Z) serves as the acid generating agent (B), the lower limit of a content of the compound (Z) in the radiation-sensitive composition with respect to 100 parts by mass of the polymer (A) is preferably 1 part by mass, more preferably 5 parts by mass, and still more preferably 10 parts by mass. The upper limit of the content is preferably 40 parts by mass, more preferably 30 parts by mass, and still more preferably 20 parts by mass.

In the case in which the compound (Z) serves as the acid diffusion control agent (C), the lower limit of a content of the compound (Z) in the radiation-sensitive composition with respect to 100 parts by mass of the polymer (A) is preferably 1 part by mass, and still more preferably 5 parts by mass. The upper limit of the content is preferably 40 parts by mass, more preferably 30 parts by mass, and still more preferably 20 parts by mass.

Each structure included in the compound (Z) is described below.

### Anion (X)

The anion (X) has an anion group. The anion group is exemplified by a monovalent organic acid anion group. Examples of the monovalent organic acid anion group include a sulfonic acid anion group (—SO₃⁻), a carboxylic acid anion group (—COO—), and a sulfonimidate anion group (—SO₂—N⁻—SO₂—). Of these, a sulfonic acid anion group or a carboxylic acid anion group is preferred.

Hereinafter, the anion (X) having a sulfonic acid anion group as the monovalent anion group is referred to as “anion (X-1)”, and the anion (X) having a carboxylic acid anion group as the monovalent anion group is referred to as “anion (X-2)”.

### Anion (X-1)

In the case in which the compound (Z) has the anion (X-1), the compound (Z) serves as the radiation-sensitive acid generating agent or the acid diffusion control agent. In the case in which the compound (Z) serves as the radiation-sensitive acid generating agent, the radiation-sensitive composition preferably contains the acid diffusion control agent. The acid diffusion control agent is exemplified by the compound (Z) in the case of serving as the acid diffusion control agent, and acid diffusion control agents other than the compound (Z) described later. Of these, the acid diffusion control agent is preferably the compound (Z) in the case of serving as the acid diffusion control agent. In other words, the radiation-sensitive composition preferably contains the compound (Z) having the anion (X-1), and the compound (Z) having the anion (X-2).

The anion (X-1) is not particularly limited as long as it can be used as an anion in a radiation-sensitive acid generating agent of onium salt type, and is exemplified by a sulfonic acid anion represented by the following formula (X-1).

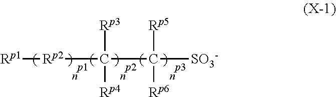

In the above formula (X-1), R^{p1} represents a monovalent group which includes a ring structure having no less than 5 ring atoms; R^{p2} represents a divalent linking group; R^{p3} and R^{p4} each independently represent a hydrogen atom, a fluorine atom, a monovalent hydrocarbon group having 1 to 20 carbon atoms, or a monovalent fluorinated hydrocarbon group having 1 to 20 carbon atoms; R^{p5} and R^{p6} each independently represent a fluorine atom or a monovalent fluorinated hydrocarbon group having 1 to 20 carbon atoms; n^{p1} is an integer of 0 to 10. n^{p2} is an integer of 0 to 10; and n^{p3} is an integer of 0 to 10, wherein a sum of n^{p1}, n^{p2}, and n^{p3} is no less than 1 and no greater than 30, and wherein in a case in which n^{p1} is no less than 2, a plurality of R^{p2}s are identical or different from each other, in a case in which n^{p2} is no less than 2, a plurality of R^{p3}s are identical or different from each other and a plurality of R^{p4}s are identical or different from each other, and in a case in which n^{p3} is no less than 2, a plurality of R^{p5}s are identical or different from each other and a plurality of R^{p6}s are identical or different from each other.

The ring structure having no less than 5 ring atoms is exemplified by the ring structures having no less than 5 ring atoms exemplified in the above section of Ring Structure (p).

In the ring structure, a part or all of hydrogen atoms bonding to the atom constituting the ring structure may be substituted with a substituent. Examples of the substituent include a halogen atom, a hydroxy group, a carboxy group, a cyano group, a nitro group, an alkyl group, a fluorinated alkyl group, an alkoxy group, an alkoxycarbonyl group, an alkoxycarbonyloxy group, an acyl group, and an acyloxy group.

In the case in which the substituent is an iodine atom, the ring structure falls under the category of the ring structure (p). In other words, the compound (Z) (more specifically, the anion (X)) will have the ring structure (p).

The lower limit of the number of ring atoms of the ring structure is preferably 6, more preferably 8, still more preferably 9, and particularly preferably 10. The upper limit of the number of ring atoms is preferably 25.

R^{p1} represents preferably a monovalent aliphatic hydrocarbon group which includes a ring structure having no less than 5 ring atoms, a monovalent group which includes an aliphatic heteroring structure having no less than 5 ring atoms, or a monovalent group which includes an aromatic hydrocarbon ring structure having no less than 6 ring atoms.

The divalent linking group represented by R^{p2} is exemplified by a carbonyl group, an ether group, a carbonyloxy group, a sulfide group, a thiocarbonyl group, a sulfonyl group, a divalent hydrocarbon group, a divalent group which includes cyclic acetal, a divalent group which includes a steroid ring, or a group obtained by combining the same, and the like.

The monovalent hydrocarbon group having 1 to 20 carbon atoms which may be represented by R^{p3} or R^{p4} is exemplified by an alkyl group having 1 to 20 carbon atoms. The monovalent fluorinated hydrocarbon group having 1 to 20 carbon atoms which may be represented by R^{p3} or R^{p4} is exemplified by a fluorinated alkyl group having 1 to 20 carbon atoms. R^{p3} and R^{p4} each represent preferably a hydrogen atom, a fluorine atom, or a fluorinated alkyl group, more preferably a hydrogen atom, a fluorine atom, or a perfluoroalkyl group, and still more preferably a hydrogen atom, a fluorine atom, or a trifluoromethyl group.

The monovalent fluorinated hydrocarbon group having 1 to 20 carbon atoms which may be represented by R^{p5} or R^{p6} is exemplified by a fluorinated alkyl group having 1 to 20 carbon atoms. R^{p5} and R^{p6} each represent preferably a fluorine atom or a fluorinated alkyl group, more preferably a fluorine atom or a perfluoroalkyl group, still more preferably a fluorine atom or a trifluoromethyl group, and particularly preferably a fluorine atom.

n^{p1} is preferably 0 to 5, more preferably 0 to 2, and still more preferably 0 or 1.

n^{p2} is preferably 0 to 5, more preferably 0 to 2, and still more preferably 0 or 1.

The lower limit of n^{p3} is preferably 1, and more preferably 2. When n^{p3} is no less than 1, strength of the acid generated by exposure can be enhanced. The upper limit of n^{p3} is preferably 4, more preferably 3, and still more preferably 2.

The lower limit of each of n^{p1}, n^{p2}, and n^{p3} is preferably 2, and more preferably 4. The upper limit of each of n^{p1}, n^{p2}, and n^{p3} is preferably 20, and more preferably 10.

Examples of the anion (X-1) include sulfonic acid anions represented by the following formulae (X-1-1) to (X-1-3).

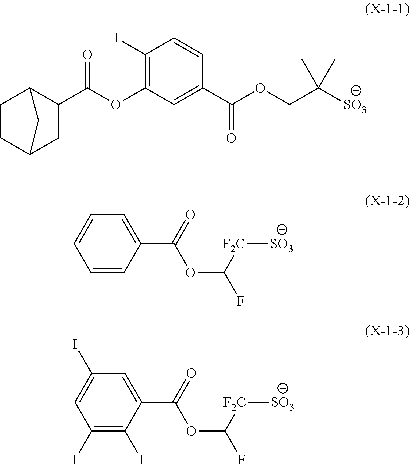

### Anion (X-2)

In a case in which the compound (Z) has an anionic moiety (X-2), the compound (Z) serves as the acid diffusion control agent. In this case, the radiation-sensitive composition preferably contains the radiation-sensitive acid generating agent. The radiation-sensitive acid generating agent is exemplified by the compound (Z) in the case of serving as the radiation-sensitive acid generating agent, and a radiation-sensitive acid generating agent other than the compound (Z) described later. In particular, the radiation-sensitive acid generating agent is preferably, for example, the compound (Z) in the case of serving as the radiation-sensitive acid generating agent.

The anion (X-2) is not particularly limited as long as it can be used as an anion in a photolabile base that generates a weak acid by photosensitization upon exposure, and is exemplified by substituted or unsubstituted salicylic acid anions, and anions obtained by replacing the sulfonic acid anion group in the above formula (X-1) with a carboxylic acid anion.

The anion (X-2) is preferably a sulfonic acid anion represented by the following formulae (X-2-1) to (X-2-5).

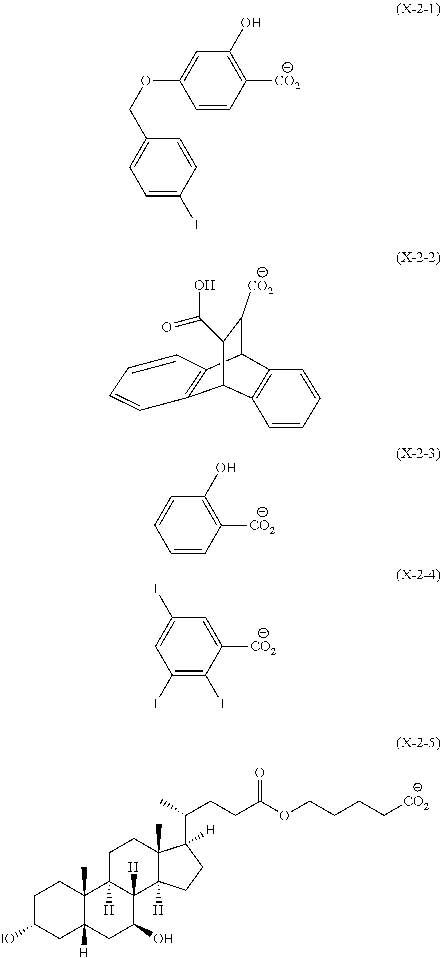

### Cation (Y)

The cation (Y) is a radiation-sensitive onium cation. A valency of the cation (Y) is not particularly limited and may be appropriately predetermined depending on a valency of the anion (X), and the cation (Y) is, for example, monovalent to trivalent, and preferably monovalent. It is to be noted that, in a case, for example, in which the anion (X) is a divalent anion and the cation (X) is a monovalent cation, the compound (Z) is an onium salt having one anion and two cations.

The cation (Y) is not particularly limited as long as it is known as a radiation-sensitive onium cation in an onium salt to be used in a radiation-sensitive acid generating agent and/or an acid diffusion control agent contained in a radiation-sensitive composition. Cation species in the case of the cation (Y) being the monovalent cation are exemplified by a sulfonium cation (S⁺) and an iodonium cation (I⁺).

In the case in which the cation (Y) is the sulfonium cation, the cation (Y) is exemplified by a monovalent cation represented by the following formula (r-a).

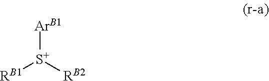

In the above formula (r-a), Ar^{B1} represents a group obtained by removing one hydrogen atom from a substituted or unsubstituted aromatic hydrocarbon ring having 6 to 20 ring atoms; and R^{B1} and R^{B2} each independently represent a group obtained by removing one hydrogen atom from a substituted or unsubstituted aromatic hydrocarbon ring having 6 to 20 ring atoms, or R^{B1} and R^{B2} taken together represent a substituted or unsubstituted polycyclic sulfur atom-containing aromatic heteroring having 9 to 30 ring atoms together with the sulfur atom to which R^{B1} and R^{B2} bond.

The aromatic hydrocarbon ring having 6 to 20 ring atoms which may be represented by Ar^{B1}, R^{B1}, or R^{B2} is exemplified by the aromatic hydrocarbon rings having 6 to 20 ring atoms exemplified in the above section of Ring Structure (p). The aromatic hydrocarbon ring having 6 to 20 ring atoms which may be represented by Ar^{B1}, R^{B1}, or R^{B2} is preferably a benzene ring.

The polycyclic sulfur atom-containing aromatic heteroring which may represented by R^{B1} and R^{B2} taken together, together with the sulfur atom to which R^{B1} and R^{B2} bond is exemplified by a dibenzothiophene ring.

In the aromatic hydrocarbon ring and the polycyclic sulfur atom-containing aromatic heteroring, at least one hydrogen atom may be substituted with a substituent. The substituent is exemplified by a halogen atom, a hydroxy group, a carboxy group, a cyano group, a nitro group, an alkyl group, a fluorinated alkyl group, an alkoxy group, an alkoxycarbonyl group, an alkoxycarbonyloxy group, an acyl group, and fan acyloxy group. The substituent is preferably an iodine atom, a fluorine atom, or a fluorinated alkyl group.

In the case in which the substituent is an iodine atom, the aromatic hydrocarbon ring and the polycyclic sulfur atom-containing aromatic heteroring fall under the category of the ring structure (p). In other words, the compound (Z) (more specifically, the cation (Y)) will have the ring structure (p).

The case in which the substituent is an iodine atom, a fluorine atom, or a fluorinated alkyl group is preferred due to a tendency to enable further improving the sensitivity.

Examples of the cation (Y) in the case of the cation (Y) being a sulfonium cation include monovalent cations represented by the following formulae (r-a-1) to (r-a-6).

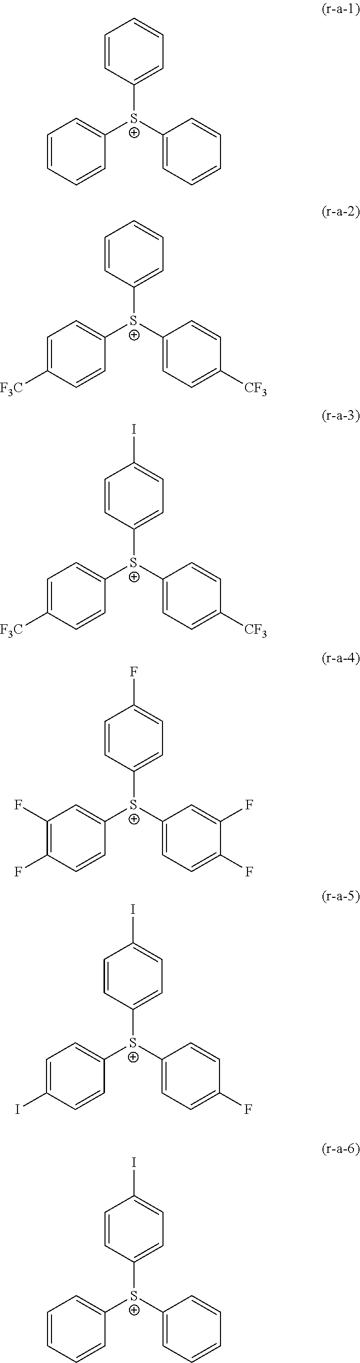 [SMILES: c1ccc([S+](c2ccccc2)c2ccccc2)cc1 ; FC(F)(F)c1ccc([S+](c2ccccc2)c2ccc(C(F)(F)F)cc2)cc1 ; FC(F)(F)c1ccc([S+](c2ccc(I)cc2)c2ccc(C(F)(F)F)cc2)cc1 ; Fc1ccc([S+](c2ccc(F)c(F)c2)c2ccc(F)c(F)c2)cc1 ; Fc1ccc([S+](c2ccc(I)cc2)c2ccc(I)cc2)cc1 ; Ic1ccc([S+](c2ccccc2)c2ccccc2)cc1]

As the compound (Z), a compound obtained by appropriately combining the anion (X) and the cation (Y) can be used.

### (D) Organic Solvent

The radiation-sensitive composition typically contains the organic solvent (D). The organic solvent (D) is not particularly limited as long as it is a solvent capable of dissolving or dispersing at least the polymer (A) and the compound (Z), as well as the other optional component(s) which may be contained as needed.

The organic solvent (D) is exemplified by an alcohol solvent, an ether solvent, a ketone solvent, an amide solvent, an ester solvent, and a hydrocarbon solvent. The radiation-sensitive composition may contain one type, or two or more types of the organic solvent (D).

Examples of the alcohol solvent include: aliphatic monohydric alcohol solvents such as 4-methyl-2-pentanol, n-hexanol, diacetone alcohol, and 2-hydroxymethyl isobutyrate; alicyclic monohydric alcohol solvents such as cyclohexanol; polyhydric alcohol solvents such as 1,2-propylene glycol; and polyhydric alcohol partial ether solvents such as propylene glycol monomethyl ether.

Examples of the ether solvent include: dialkyl ether solvents such as diethyl ether, dipropyl ether, dibutyl ether, dipentyl ether, diisoamyl ether, dihexyl ether, and diheptyl ether; cyclic ether solvents such as tetrahydrofuran and tetrahydropyran; and aromatic ring-containing ether solvents such as diphenyl ether and anisole.

Examples of the ketone solvent include: chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethylnonanone; cyclic ketone solvents such as cyclopentanone, cyclohexanone, cycloheptanone, cyclooctanone, and methylcyclohexanone; and 2,4-pentanedione, acetonylacetone, and acetophenone.

Examples of the amide solvent include: cyclic amide solvents such as N,N′-dimethylimidazolidinone and N-methylpyrrolidone; and chain amide solvents such as N-methylformamide, N,N-dimethylformamide, N,N-diethylformamide, acetamide, N-methylacetamide, N,N-dimethylacetamide, and N-methylpropionamide.

Examples of the ester solvent include: monocarboxylic acid ester solvents such as n-butyl acetate and ethyl lactate; lactone solvents such as γ-butyrolactone and valerolactone; polyhydric alcohol carboxylate solvents such as propylene glycol acetate; polyhydric alcohol partial ether carboxylate solvents such as propylene glycol monomethyl ether acetate; polyhydric carboxylic acid diester solvents such as diethyl oxalate; and carbonate solvents such as dimethyl carbonate and diethyl carbonate.

Examples of the hydrocarbon solvent include: aliphatic hydrocarbon solvents such as n-pentane and n-hexane; and aromatic hydrocarbon solvents such as toluene and xylene.

The organic solvent (D) is preferably the alcohol solvent, the ester solvent, or a combination of the same, more preferably the polyhydric alcohol partial ether solvent, the polyhydric alcohol partial ether carboxylate solvent, or a combination of the same, and still more preferably propylene glycol 1-monomethyl ether, propylene glycol monomethyl ether acetate, or a combination of the same.

In the case of the radiation-sensitive composition containing the organic solvent (D), the lower limit of a proportion of the organic solvent (D) with respect to total components contained in the radiation-sensitive composition is preferably 50% by mass, more preferably 60% by mass, still more preferably 70% by mass, and particularly preferably 80% by mass. The upper limit of the proportion is preferably 99.9% by mass, more preferably 99.5% by mass, and still more preferably 99.0% by mass.

### (F) Polymer

The polymer (F) is a polymer being different from the polymer (A) and having a percentage content of fluorine atoms greater than that of the polymer (A). In general, a polymer being more hydrophobic than a polymer to be the base polymer tends to be localized in a resist film surface layer. Since the polymer (F) has a percentage content of fluorine atoms greater than that of the polymer (A), the polymer (F) tends to be localized in the resist film surface layer due to the characteristic resulting from hydrophobicity. As a result, in the case of the radiation-sensitive composition containing the polymer (F), a cross-sectional shape of a resist pattern to be formed is expected to be favorable. The radiation-sensitive composition may contain the polymer (F) as, for example, a surface-adjusting agent of a resist film. The radiation-sensitive composition may contain one type, or two or more types of the polymer (F).

### Other Optional Component(s)

The other optional component(s) is/are exemplified by an acid generating agent other than the compound (Z), an acid diffusion control agent other than the compound (Z), a surfactant, and the like. The radiation-sensitive composition may contain one type, or two or more types each of the other optional component(s).

The acid generating agent other than the compound (Z) is exemplified by an N-sulfonyloxyimide compound, a sulfonimide compound, a halogen-containing compound, and a diazo ketone compound.

The acid diffusion control agent other than the compound (Z) is exemplified by a nitrogen atom-containing compound. Examples of the nitrogen atom-containing compound include: amine compounds such as tripentylamine and trioctylamine; amide group-containing compounds such as formamide and N,N-dimethylacetamide; urea compounds such as urea and 1,1-dimethylurea; nitrogen-containing heterocyclic compounds such as pyridine, N-(undecylcarbonyloxyethyl) morpholine, N-t-pentyloxycarbonyl-4-hydroxypiperidine; and the like.

### Method of Forming Resist Pattern

The method of forming a resist pattern according to the other embodiment of the present disclosure includes: a step (hereinafter, may be also referred to as “applying step”) of applying a radiation-sensitive composition directly or indirectly on a substrate; a step (hereinafter, may be also referred to as “exposing step”) of exposing a resist film formed by the applying step; and a step (hereinafter, may be also referred to as “developing step”) of developing the resist film exposed.

In the applying step, the radiation-sensitive composition of the one embodiment of the present disclosure is used as the radiation-sensitive composition. Therefore, the method of forming a resist pattern enables a resist pattern that is superior in resolution and CDU to be formed with favorable sensitivity.

Each step included in the method of forming a resist pattern will be described below.

### Applying Step

In this step, a radiation-sensitive composition is applied directly or indirectly on the substrate. By this step, the resist pattern is formed directly or indirectly on the substrate.

In this step, the radiation-sensitive composition of the one embodiment of the present disclosure, described above, is used as the radiation-sensitive composition.

The substrate is exemplified by a conventionally well-known substrate such as a silicon wafer and a wafer coated with silicon dioxide or aluminum.

An application procedure is exemplified by spin coating, cast coating, roll coating, and the like. After the application, prebaking (hereinafter, may be also referred to as “PB”) may be carried out as needed for evaporating the solvent remaining in the coating film. A PB temperature and a PB time period are not particularly limited, and for example, PB may be carried out at a temperature of no lower than 60° C. and no higher than 150° C. for a time period of no less than 5 sec and no greater than 300 sec. An average thickness of the resist film to be formed is not particularly limited, and may be, for example, no less than 10 nm and no greater than 1,000 nm.

### Exposing Step

In this step, the resist film formed by the applying step is exposed. This exposure is carried out by irradiation with a radioactive ray through a photomask (as the case may be, through a liquid immersion medium such as water). As the radioactive ray, far ultraviolet rays, EUV, or electron beams are preferred; an ArF excimer laser beam (wavelength: 193 nm), a KrF excimer laser beam (wavelength: 248 nm), EUV (wavelength: 13.5 mm), or an electron beam is more preferred; a KrF excimer laser beam, EUV, or an electron beam is still more preferred; and EUV or an electron beam is particularly preferred.

It is preferred that post exposure baking (hereinafter, may be also referred to as “PEB”) is carried out after the exposure. This PEB enables an increase in the difference in solubility of the resist film in a developer solution between the light-exposed regions and light-unexposed regions. A PEB temperature and a PEB time period are not particularly limited, and for example, PEB may be carried out at a temperature of no lower than 50° C. and no higher than 180° C. for a time period of no less than 5 sec and no greater than 600 sec.

### Developing Step

In this step, the resist film exposed is developed. Accordingly, formation of a predetermined resist pattern is enabled. The development procedure in the developing step may be carried out by either development with an alkali, or development with an organic solvent.

In the case of the development with an alkali, the developer solution for use in the development is exemplified by: alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethylammonium hydroxide (hereinafter, may be also referred to as “TMAH”), pyrrole, piperidine, choline, 1,8-diazabicyclo-[5.4.0]-7-undecene, and 1,5-diazabicyclo-[4.3.0]-5-nonene. Of these, an aqueous TMAH solution is preferred, and a 2.38% by mass aqueous TMAH solution is more preferred.

In the case of the development with an organic solvent, the developer solution is exemplified by the organic solvents exemplified as the organic solvent (D) in the radiation-sensitive composition described above.

### EXAMPLES

Hereinafter, the present invention is explained in detail by way of Examples, but the present invention is not in any way limited to these Examples. Measuring methods for various types of physical property values are shown below.

### Proportion of Structural Unit Contained

The proportion of the structural unit contained in the polymer was measured by a ¹H-NMR analysis, using a nuclear magnetic resonance apparatus (“JNM-Delta400”, available from JEOL, Ltd.).

Weight Average Molecular Weight (Mw), Number Average Molecular Weight (Mn) and Mw/Mn

Measurements of the Mw and the Mn of the polymer were carried out in accordance with the conditions described in the above paragraph “Method for Measuring Mw and Mn”. The Mw/Mn of the polymer was calculated from the measurement results of the Mw and the Mn.

### Synthesis of Polymer (A)

### Synthesis Examples 1 to 25: Syntheses of Polymers (P-1) to (P-24) and (Pc-1)

Polymers (P-1) to (P-24) and (Pc-1) shown in Table 1 below were obtained by combining the monomer that gives each structural unit presented below and carrying out a copolymerization reaction in a tetrahydrofuran (THF) solvent, followed by isolation and drying.

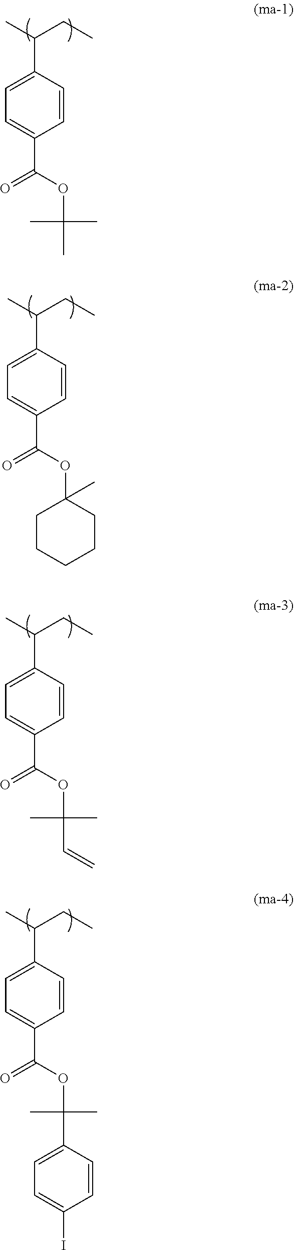

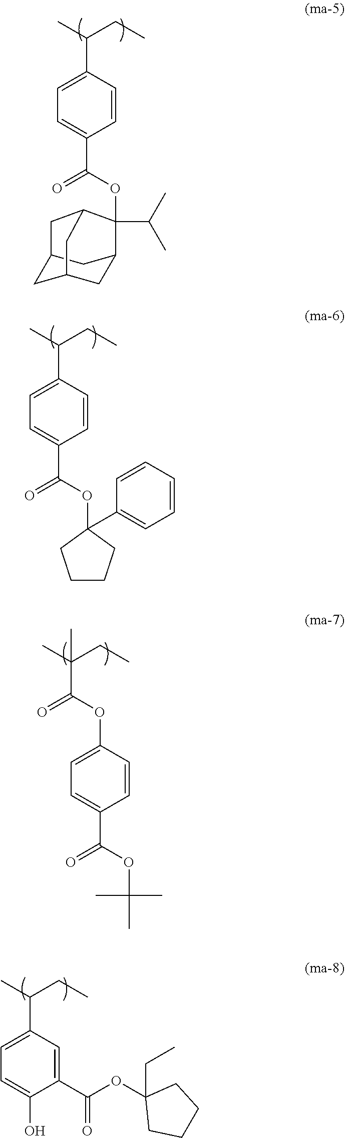

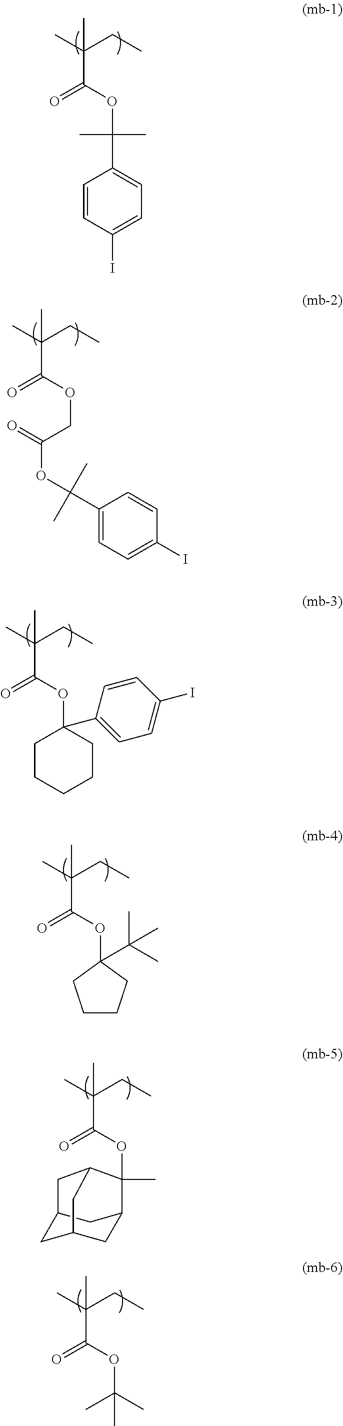

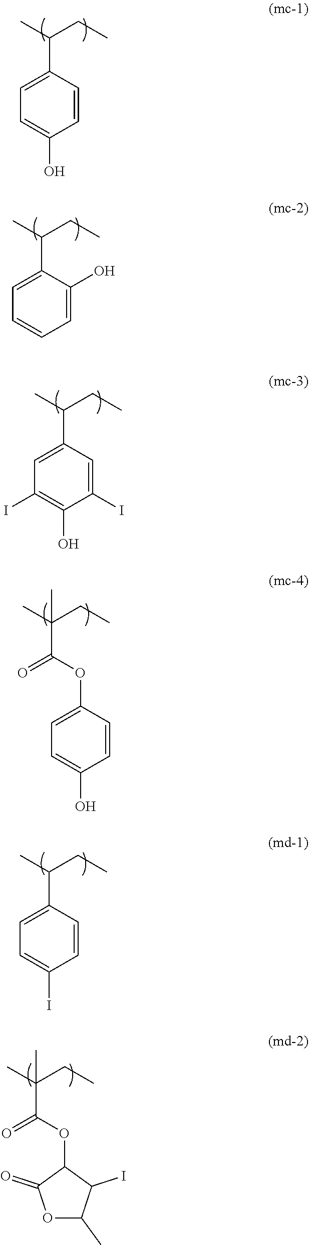

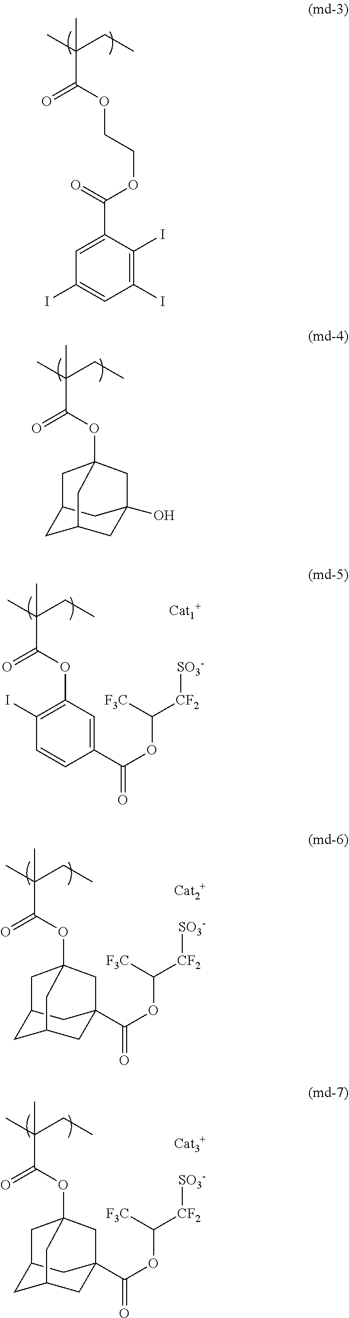

Cat₁⁺ in the above formula (md-5) is tris(4-fluorophenyl) sulfonium. Cat₂⁺ in the above formula (md-6) is (4-iodophenyl)diphenyl sulfonium. Cat₃⁺ in the above formula (md-7) is triphenylsulfonium.

In Table 1 below, “-” denotes that a corresponding structural unit was not contained, and “mol %” indicates the proportion of each structural unit with respect to the total structural units constituting the polymer (A).

TABLE 1

| | | Structural unit | | Structural unit | | Structural unit | | Structural unit | | | |
|---|---|---|---|---|---|---|---|---|---|---|---|
| | (A) | ma | | mb | | mc | | md | | | Mw/ |
| | Polymer | type | mol % | type | mol % | type | mol % | type | mol % | Mw | Mn |
| Synthesis | P-1 | ma-1 | 20 | mb-4/ | 15/5 | mc-1/ | 30/20 | md-4 | 10 | 8,800 | 1.7 |
| Example 1 | | | | mb-5 | | mc-3 | | | | | |
| Synthesis | P-2 | ma-2 | 20 | mb-4/ | 15/5 | mc-1/ | 30/20 | md-4 | 10 | 8,700 | 1.7 |
| Example 2 | | | | mb-5 | | mc-3 | | | | | |
| Synthesis | P-3 | ma-3 | 20 | mb-4/ | 15/5 | mc-1/ | 30/20 | md-4 | 10 | 8,600 | 1.7 |
| Example 3 | | | | mb-5 | | mc-3 | | | | | |
| Synthesis | P-4 | ma-4 | 20 | mb-4/ | 15/5 | mc-1/ | 30/20 | md-4 | 10 | 8,600 | 1.7 |
| Example 4 | | | | mb-5 | | mc-3 | | | | | |
| Synthesis | P-5 | ma-5 | 20 | mb-4/ | 15/5 | mc-1/ | 30/20 | md-4 | 10 | 8,300 | 1.7 |
| Example 5 | | | | mb-5 | | mc-3 | | | | | |
| Synthesis | P-6 | ma-6 | 20 | mb-4/ | 15/5 | mc-1/ | 30/20 | md-4 | 10 | 8,600 | 1.7 |
| Example 6 | | | | mb-5 | | mc-3 | | | | | |
| Synthesis | P-7 | ma-7 | 20 | mb-4/ | 15/5 | mc-1/ | 30/20 | md-4 | 10 | 9,200 | 1.7 |
| Example 7 | | | | mb-5 | | mc-3 | | | | | |
| Synthesis | P-8 | ma-8 | 20 | mb-4/ | 15/5 | mc-1/ | 30/20 | md-4 | 10 | 8,500 | 1.7 |
| Example 8 | | | | mb-5 | | mc-3 | | | | | |
| Synthesis | P-9 | ma-2 | 15 | mb-4 | 25 | mc-4 | 40 | mb-4/ | 10/10 | 8,000 | 1.8 |
| Example 9 | | | | | | | | mb-5 | | | |
| Synthesis | P-10 | ma-2 | 15 | mb-4 | 25 | mc-4 | 40 | md-4/ | 10/10 | 7,800 | 1.8 |
| Example 10 | | | | | | | | md-6 | | | |
| Synthesis | P-11 | ma-2 | 15 | mb-4 | 25 | mc-4 | 40 | md-4/ | 10/10 | 8,200 | 1.8 |
| Example 11 | | | | | | | | md-7 | | | |
| Synthesis | P-12 | ma-1 | 20 | mb-1 | 20 | mc-1/ | 30/20 | md-4 | 10 | 9,400 | 1.7 |
| Example 12 | | | | | | mc-3 | | | | | |
| Synthesis | P-13 | ma-1 | 20 | mb-2 | 20 | mc-1/ | 30/20 | md-4 | 10 | 9,400 | 1.7 |
| Example 13 | | | | | | mc-3 | | | | | |
| Synthesis | P-14 | ma-1 | 20 | mb-3 | 20 | mc-1/ | 30/20 | md-4 | 10 | 9,200 | 1.7 |
| Example 14 | | | | | | mc-3 | | | | | |
| Synthesis | P-15 | ma-4 | 20 | mb-4/ | 15/5 | mc-1 | 50 | md-4 | 10 | 9,000 | 1.7 |
| Example 15 | | | | mb-5 | | | | | | | |
| Synthesis | P-16 | ma-4 | 20 | mb-4/ | 15/5 | mc-2 | 50 | md-4 | 10 | 8,900 | 1.7 |
| Example 16 | | | | mb-5 | | | | | | | |
| Synthesis | P-17 | ma-4 | 50 | — | — | mc-1 | 50 | — | — | 10,100 | 1.6 |
| Example 17 | | | | | | | | | | | |
| Synthesis | P-18 | ma-1 | 20 | mb-4/ | 15/5 | mc-1 | 50 | md-1 | 10 | 9,300 | 1.7 |
| Example 18 | | | | mb-5 | | | | | | | |
| Synthesis | P-19 | ma-1 | 20 | mb-4/ | 15/5 | mc-1 | 50 | md-2 | 10 | 9,100 | 1.7 |
| Example 19 | | | | mb-5 | | | | | | | |
| Synthesis | P-20 | ma-1 | 20 | mb-4/ | 15/5 | mc-1 | 50 | md-3 | 10 | 9,000 | 1.7 |
| Example 20 | | | | mb-5 | | | | | | | |
| Synthesis | P-21 | ma-4 | 15 | mb-2/ | 15/15 | mc-3/ | 5/35 | md-2 | 15 | 8,800 | 1.7 |
| Example 21 | | | | mb-6 | | mc-4 | | | | | |
| Synthesis | P-22 | ma-3 | 20 | mb-4/ | 15/5 | mc-1 | 50 | md-4 | 10 | 9,100 | 1.7 |
| Example 22 | | | | mb-5 | | | | | | | |
| Synthesis | P-23 | ma-6 | 20 | mb-4 | 40 | mc-2 | 40 | — | — | 9,500 | 1.7 |
| Example 23 | | | | | | | | | | | |
| Synthesis | P-24 | ma-1 | 20 | mb-3 | 20 | mc-1 | 50 | md-4 | 10 | 9,500 | 1.7 |
| Example 24 | | | | | | | | | | | |
| Synthesis | Pc-1 | — | — | mb-1 | 40 | mc-1 | 50 | md-4 | 10 | 9,400 | 1.7 |
| Example 25 | | | | | | | | | | | |

### Preparation of Radiation-Sensitive Composition

The acid generating agent (B), the acid diffusion control agent (C), the organic solvent (D), and the polymer (F) used for preparing the radiation-sensitive composition are shown below. In the following Examples and Comparative Examples, unless otherwise specified particularly, the term “parts by mass” means a value, provided that the mass of the polymer (A) used was 100 parts by mass.

### (B) Acid Generating Agent

Acid generating agents (PAG1) to (PAG4) shown below were used as the acid generating agent (B).

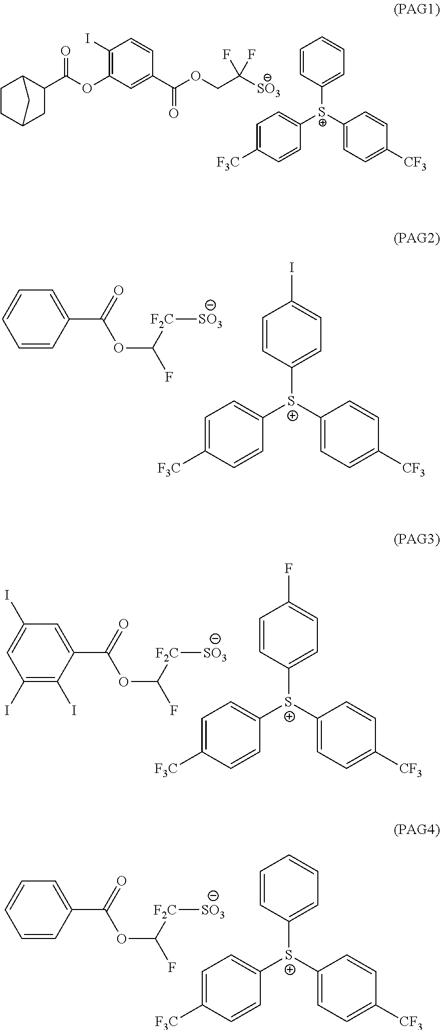

### (C) Acid Diffusion Control Agent

Acid diffusion control agents (Q-1) to (Q-6) shown below were used as the acid diffusion control agent (C).

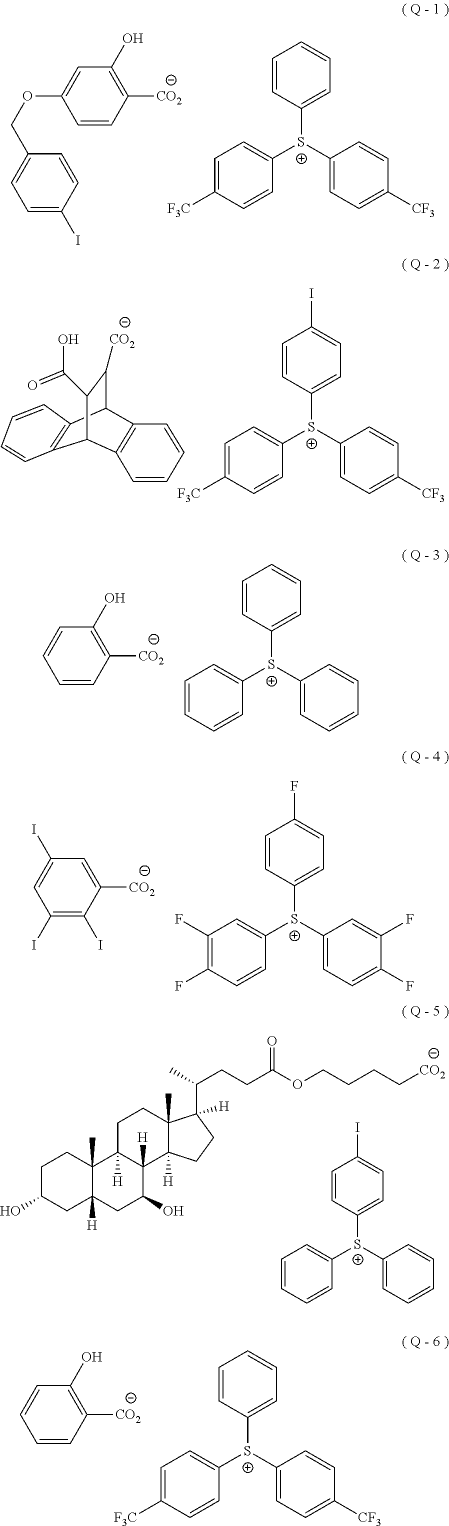

### (D) Organic Solvent

Organic solvents shown below were used as the organic solvent (D).
PGMEA: propylene glycol monomethyl ether acetate
PGME: propylene glycol monomethyl ether
DAA: diacetone alcohol

### (F) Polymer

A polymer (F-1) shown below was used as the polymer (F). In the following formula (F-1), the numerical value inscribed at the bottom right of the structural unit indicates the proportion (molar ratio) of the structural unit, with respect to the total structural units constituting the polymer (F). The polymer (F-1) had Mw of 8,900, and Mw/Mn of 2.0.

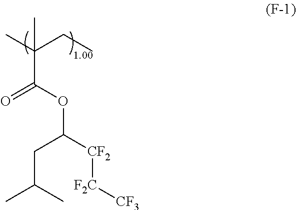

### Examples 1 to 33 and Comparative Examples 1 to 2

Each component shown in Table 2 below was dissolved in the organic solvent (D) shown in Table 2 below, in which a surfactant (“FC-4430”, available from 3M Company) had been dissolved at a concentration of 100 ppm. A mix liquid thus obtained was filtered through a membrane filter having a pore size of 0.2 μm to prepare each radiation-sensitive composition. In Table 2 below, “-” denotes that a corresponding component was not contained.

### Evaluations

Using the radiation-sensitive composition prepared as described above, sensitivity, resolution, and CDU were evaluated in accordance with the following methods. The results of the evaluations are shown in Table 2 below.

### Sensitivity

An underlayer antireflective film having an average thickness of 10 nm was formed by applying a composition for underlayer antireflective film formation (“ARC66,” available from Brewer Science, Inc.) on a 12-inch silicon wafer using a spin-coater (“CLEAN TRACK ACT 12,” available from Tokyo Electron Limited), and thereafter heating the composition at 205° C. for 60 sec. Each radiation-sensitive composition prepared as described above was applied on the underlayer antireflective film using the spin-coater, and subjected to PB at 130° C. for 60 sec. Thereafter, by cooling at 23° C. for 30 sec, a resist film having an average thickness of 55 nm was formed. This resist film was exposed with an EUV scanner (“NXE3300”, available from ASML Co.: NA of 0.33, σ 0.9/0.6, quadruple pole illumination, mask of a hole pattern with a dimension on the wafer of pitch: 46 nm, +20% bias). PEB was carried out on a hot plate at 120° C. for 60 sec, and development was performed with a 2.38% by mass aqueous TMAH solution for 30 sec, whereby a resist pattern having 23 nm holes and 46 nm pitches was formed. An exposure dose at which this resist pattern with the 23 nm holes and 46 nm pitches was formed was defined as an optimum exposure dose (Eop, unit: mJ/cm²). The Eop being smaller indicates more favorable sensitivity.

### Resolution

In the method of forming a resist pattern described in the above section of Sensitivity, a minimum diameter of the contact holes resolved with the exposure dose being changed was measured, and the measurement value was used as a resolution (unit: nm). The resolution value being smaller indicates more favorable resolution.

### CDU

A resist pattern with 23 nm holes and 46 nm pitches was formed through irradiation with the Eop exposure dose determined in the above section of Sensitivity, in a similar manner to the above section of Sensitivity. The resist pattern thus formed was observed from above using a scanning electron microscope (“CG-5000”, available from Hitachi High-Technologies Corporation). Hole diameters were measured at 16 sites in an area of 500 nm, and the averaged value was determined. Furthermore, the average value was measured at 500 arbitrary sites in total. A 3 Sigma value was determined from distribution of the measurement values, and thus determined 3 Sigma value was defined as “CDU” (units: nm). The CDU being smaller indicates being more favorable, revealing less variance of the hole diameters in greater ranges.

TABLE 2

| | | | (C) Acid | | | | | |
|---|---|---|---|---|---|---|---|---|
| | | | diffusion | | | | | |
| | (A) | (B) Acid | control | | (F) | | | |
| | Polymer | generating | agent | (D) Organic | Polymer | | | |
| | (parts by | agent (parts | (parts by | solvent (parts | (parts by | Sensitivity | Resolution | CDU |
| | mass) | by mass) | mass) | by mass) | mass) | [mJ/cm²] | [nm] | [nm] |
| Example 1 | P-1 (100) | PAG4 (15) | Q-6 (8) | PGMEA/PGME | F-1 (3) | 13 | 20 | 2.2 |
| | | | | (2,000/500) | | | | |
| Example 2 | P-2 (100) | PAG4 (15) | Q-6 (8) | PGMEA/PGME | F-1 (3) | 13 | 20 | 2.2 |
| | | | | (2,000/500) | | | | |
| Example 3 | P-3 (100) | PAG4 (15) | Q-6 (8) | PGMEA/PGME | F-1 (3) | 13 | 19 | 2.2 |
| | | | | (2,000/500) | | | | |
| Example 4 | P-4 (100) | PAG4 (15) | Q-6 (8) | PGMEA/PGME | F-1 (3) | 12 | 19 | 2.1 |
| | | | | (2,000/500) | | | | |
| Example 5 | P-5 (100) | PAG4 (15) | Q-6 (8) | PGMEA/PGME | F-1 (3) | 13 | 21 | 2.2 |
| | | | | (2,000/500) | | | | |
| Example 6 | P-6 (100) | PAG4 (15) | Q-6 (8) | PGMEA/PGME | F-1 (3) | 13 | 19 | 2.2 |
| | | | | (2,000/500) | | | | |
| Example 7 | P-7 (100) | PAG4 (15) | Q-6 (8) | PGMEA/PGME | F-1 (3) | 13 | 20 | 2.2 |
| | | | | (2,000/500) | | | | |
| Example 8 | P-8 (100) | PAG4 (15) | Q-6 (8) | PGMEA/PGME | F-1 (3) | 13 | 20 | 2.1 |
| | | | | (2,000/500) | | | | |
| Example 9 | P-9 (100) | — | Q-6 (8) | PGMEA/DAA | — | 14 | 21 | 2.0 |
| | | | | (2,200/300) | | | | |
| Example 10 | P-10 (100) | — | Q-6 (8) | PGMEA/DAA | — | 14 | 21 | 2.0 |
| | | | | (2,200/300) | | | | |
| Example 11 | P-11 (100) | — | Q-1 (8) | PGMEA/DAA | — | 14 | 20 | 2.1 |
| | | | | (2,200/300) | | | | |
| Example 12 | P-12 (100) | PAG4 (15) | Q-6 (8) | PGMEA/PGME | F-1 (3) | 12 | 20 | 2.1 |
| | | | | (2,000/500) | | | | |
| Example 13 | P-13 (100) | PAG4 (15) | Q-6 (8) | PGMEA/PGME | F-1 (3) | 12 | 20 | 2.1 |
| | | | | (2,000/500) | | | | |
| Example 14 | P-14 (100) | PAG4 (15) | Q-6 (8) | PGMEA/PGME | F-1 (3) | 12 | 20 | 2.1 |
| | | | | (2,000/500) | | | | |
| Example 15 | P-15 (100) | PAG4 (15) | Q-6 (8) | PGMEA/PGME | F-1 (3) | 13 | 19 | 2.2 |
| | | | | (2,000/500) | | | | |
| Example 16 | P-16 (100) | PAG4 (15) | Q-6 (8) | PGMEA/PGME | F-1 (3) | 13 | 19 | 2.2 |
| | | | | (2,000/500) | | | | |
| Example 17 | P-17 (100) | PAG4 (15) | Q-6 (8) | PGMEA/PGME | F-1 (3) | 12 | 19 | 2.1 |
| | | | | (2,000/500) | | | | |
| Example 18 | P-18 (100) | PAG4 (15) | Q-6 (8) | PGMEA/PGME | F-1 (3) | 13 | 20 | 2.3 |
| | | | | (2,000/500) | | | | |
| Example 19 | P-19 (100) | PAG4 (15) | Q-6 (8) | PGMEA/PGME | F-1 (3) | 14 | 20 | 2.2 |
| | | | | (2,000/500) | | | | |
| Example 20 | P-20 (100) | PAG4 (15) | Q-6 (8) | PGMEA/PGME | F-1 (3) | 13 | 19 | 2.3 |
| | | | | (2,000/500) | | | | |
| Example 21 | P-21 (100) | PAG4 (15) | Q-6 (8) | PGMEA/PGME | F-1 (3) | 12 | 19 | 2.1 |
| | | | | (2,000/500) | | | | |
| Example 22 | P-1 (100) | PAG4 (15) | Q-1 (8) | PGMEA/PGME | F-1 (3) | 13 | 20 | 2.2 |
| | | | | (2,000/500) | | | | |
| Example 23 | P-1 (100) | PAG4 (15) | Q-2 (8) | PGMEA/PGME | F-1 (3) | 13 | 20 | 2.2 |
| | | | | (2,000/500) | | | | |
| Example 24 | P-1 (100) | PAG1 (15) | Q-3 (8) | PGMEA/PGME | F-1 (3) | 13 | 20 | 2.2 |
| | | | | (2,000/500) | | | | |
| Example 25 | P-1 (100) | PAG2 (15) | Q-3 (8) | PGMEA/PGME | F-1 (3) | 13 | 20 | 2.2 |
| | | | | (2,000/500) | | | | |
| Example 26 | P-14 (100) | PAG3 (15) | Q-4 (8) | PGMEA/PGME | F-1 (3) | 12 | 20 | 2.0 |
| | | | | (2,000/500) | | | | |
| Example 27 | P-14 (100) | PAG4 (15) | Q-5 (8) | PGMEA/DAA | F-1 (3) | 12 | 20 | 2.1 |
| | | | | (2,200/300) | | | | |
| Example 28 | P-22 (100) | PAG4 (15) | Q-1 (8) | PGMEA/PGME | F-1 (3) | 13 | 19 | 2.3 |
| | | | | (2,000/500) | | | | |
| Example 29 | P-22 (100) | PAG4 (15) | Q-2 (8) | PGMEA/PGME | F-1 (3) | 13 | 19 | 2.3 |
| | | | | (2,000/500) | | | | |
| Example 30 | P-22 (100) | PAG1 (15) | Q-3 (8) | PGMEA/PGME | F-1 (3) | 13 | 19 | 2.3 |
| | | | | (2,000/500) | | | | |
| Example 31 | P-22 (100) | PAG2 (15) | Q-3 (8) | PGMEA/PGME | F-1 (3) | 13 | 19 | 2.3 |
| | | | | (2,000/500) | | | | |
| Example 32 | P-23 (100) | PAG4 (15) | Q-1 (8) | PGMEA/PGME | F-1 (3) | 13 | 19 | 2.3 |
| | | | | (2,000/500) | | | | |
| Example 33 | P-24 (100) | PAG4 (15) | Q-6 (8) | PGMEA/PGME | F-1 (3) | 13 | 19 | 2.2 |
| | | | | (2,000/500) | | | | |
| Comparative | Pc-1 (100) | PAG4 (15) | Q-1 (8) | PGMEA/PGME | F-1 (3) | 14 | 23 | 2.3 |
| Example 1 | | | | (2,000/500) | | | | |
| Comparative | P-22 (100) | PAG4 (15) | Q-6 (8) | PGMEA/PGME | F-1 (3) | 14 | 20 | 2.3 |
| Example 2 | | | | (2,000/500) | | | | |

Obviously, numerous modifications and variations of the present invention(s) are possible in light of the above teachings. It is therefore to be understood that within the scope of the appended claims, the invention(s) may be practiced otherwise than as specifically described herein.

What is claimed is:

1. A radiation-sensitive composition comprising:
a polymer comprising a first structural unit represented by formula (1); and
a compound comprising an anion and a radiation-sensitive onium cation, wherein
at least one of the polymer and the compound has a ring structure having at least one iodine atom bonded to the ring structure, 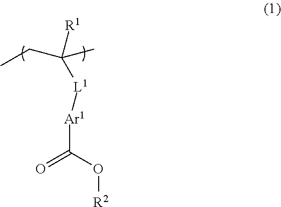
wherein, in the formula (1), R¹ represents a hydrogen atom, a fluorine atom, a methyl group, or a trifluoromethyl group; L¹ represents a single bond, —COO—, or —CONH—; Ar¹ represents a group obtained by removing two hydrogen atoms from a substituted or unsubstituted aromatic hydrocarbon ring; and R² represents an acid-labile group.

2. The radiation-sensitive composition according to claim 1, wherein the acid-labile group does not comprise a polycyclic aliphatic ring.

3. The radiation-sensitive composition according to claim 1, wherein the acid-labile group comprises an aromatic ring or a carbon-carbon double bond.

4. The radiation-sensitive composition according to claim 1, wherein the acid-labile group comprises an aromatic ring having at least one iodine atom bonded to the aromatic ring.

5. The radiation-sensitive composition according to claim 1, wherein the radiation-sensitive onium cation further comprises an aromatic ring having at least one fluorine atom or at least one fluorine atom-containing group, the at least one fluorine atom and the at least one fluorine atom-containing group being bonded to the aromatic ring.

6. The radiation-sensitive composition according to claim 1, wherein the polymer further comprises a second structural unit comprising a ring structure having at least one iodine atom bonded to the ring structure.

7. The radiation-sensitive composition according to claim 6, wherein the ring structure comprised in the second structural unit is an aromatic ring having at least one iodine atom bonded to the aromatic ring.

8. A method of forming a resist pattern, the method comprising:
applying the radiation-sensitive composition according to claim 1 directly or indirectly on a substrate to form a resist film;
exposing the resist film; and
developing the resist film exposed.

9. The method according to claim 8, wherein the acid-labile group does not comprise a polycyclic aliphatic ring.

10. The method according to claim 8, wherein the acid-labile group comprises an aromatic ring or a carbon-carbon double bond.

11. The method according to claim 8, wherein the acid-labile group comprises an aromatic ring having at least one iodine atom bonded to the aromatic ring.

12. The method according to claim 8, wherein the radiation-sensitive onium cation further comprises an aromatic ring having at least one fluorine atom or at least one fluorine atom-containing group, the at least one fluorine atom and the at least one fluorine atom-containing group being bonded to the aromatic ring.

13. The method according to claim 8, wherein the polymer further comprises a second structural unit comprising a ring structure having at least one iodine atom bonded to the ring structure.

14. The method according to claim 13, wherein the ring structure comprised in the second structural unit is an aromatic ring having at least one iodine atom bonded to the aromatic ring.
